(19) United States
(12) Patent Application Publication
(10) Pub. No.: US 2017/0084451 A1
(43) Pub. Date: Mar. 23, 2017

(54) FILM PATTERNING METHOD

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Li LI, Beijing (CN); Zhilong PENG, Beijing (CN); Wukun DAI, Beijing (CN); Yiping DONG, Beijing (CN)

(73) Assignees: BOE TECHNOLOGY GROUP CO., LTD., Beijing (CN); BEIJING BOE OPTOELECTRONICS TECHNOLOGY CO., LTD., Beijing (CN)

(21) Appl. No.: 15/133,477

(22) Filed: Apr. 20, 2016

(30) Foreign Application Priority Data
Sep. 23, 2015 (CN) 201510614255.1

(51) Int. Cl. H01L 21/027; G03F 7/32; G03F 7/20; H01L 21/4763; H01L 21/467

(52) U.S. Cl. CPC H01L 21/0273; H01L 21/47635; H01L 21/467; G03F 7/20; G03F 7/32

(57) ABSTRACT

A film patterning method is provided. The method includes: forming a to-be-patterned film on a surface of a base substrate; forming a protective layer for blocking foreign materials on a surface of the to-be-patterned film, before moving the base substrate to an etching device to pattern the to-be-patterned film; and forming a patterned mask, and etching the to-be-patterned film with the patterned mask so as to form a patterned film.

### TECHNICAL FIELD

Embodiments of the present disclosure relate to a film patterning method.

### BACKGROUND

Currently, important parts inside a substrate include various films with patterns, and in a film patterning production process, various foreign materials are easy to fall on a surface of a to-be-patterned film, so that residues of the film will be left in an etching process, thereby causing a poor display effect.

### SUMMARY

One embodiment of the present disclosure provides a film patterning method, comprising: forming a to-be-patterned film on a surface of a base substrate; forming a protective layer configured for blocking foreign materials on a surface of the to-be-patterned film, before moving the base substrate to an etching device to pattern the to-be-patterned film; and forming a patterned mask, and etching the to-be-patterned film with the patterned mask so as to form a patterned film.

In some examples, the to-be-patterned film includes a to-be-removed region and a to-be-retained region.

In some examples, before the patterned mask is formed, the protective layer completely covers the to-be-removed region and the to-be-retained region of the to-be-patterned film.

In some examples, the patterned mask is obtained by patterning the protective layer.

In some examples, forming the protective layer configured for blocking foreign materials on the surface of the to-be-patterned film before patterning the to-be-patterned film includes: forming a photoresist layer on the surface of the to-be-patterned film, before patterning the to-be-patterned film; and carrying out exposure and development on the photoresist layer to form the protective layer, wherein a thickness of the protective layer correspondingly covering the to-be-removed region is smaller than that of the protective layer correspondingly covering the to-be-retained region.

In some examples, carrying out exposure and development on the photoresist layer to form the protective layer includes: carrying out exposure and development on the photoresist layer with a mask plate so as to form the protective layer.

In some examples, the mask plate is a halftone mask plate, a graytone mask plate or a mask plate with a slit.

In some examples, forming the patterned mask includes: partially ashing the protective layer, to remove a part of the protective layer correspondingly covering the to-be-removed region, and thin a part of the protective layer correspondingly covering the to-be-retained region, so as to form the patterned mask, wherein the patterned mask completely exposes the to-be-removed region, and completely covers the to-be-retained region.

In some examples, after forming the patterned film, the method further comprises: removing the patterned mask on the patterned film.

In some examples, the patterned film is at least one selected from the group consisted of an active layer, an ohmic contact layer, a source/drain electrode, a pixel electrode layer and a touch control electrode layer.

In some examples, forming the patterned mask is carried out in the etching device.

In some examples, partially ashing the protective layer is carried out in the etching device.

In some examples, the protective layer is made of a photoresist material.

### BRIEF DESCRIPTION OF THE DRAWINGS

In order to more clearly illustrate the technical solution of the embodiments of the present disclosure, the drawings of the embodiments will be briefly described in the followings, and it is obvious that the described drawings are only related to some embodiments of the present disclosure and thus are not limitative of the present disclosure.

FIG. 1a to FIG. 1d respectively are structural schematic diagrams of an active layer patterning method after respective steps are executed;

FIG. 2 is a first flow chart of a film patterning method provided by an embodiment of the present disclosure;

FIG. 3 is a second flow chart of the film patterning method provided by an embodiment of the present disclosure; and

FIG. 4a to FIG. 4e respectively are structural schematic diagrams of an active layer patterning method provided by an embodiment of the present disclosure after respective steps are executed.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

A thickness and a shape of each film in the drawings do not reflect a true scale of a film pattern, and only aims to schematically illustrate contents of the present disclosure.

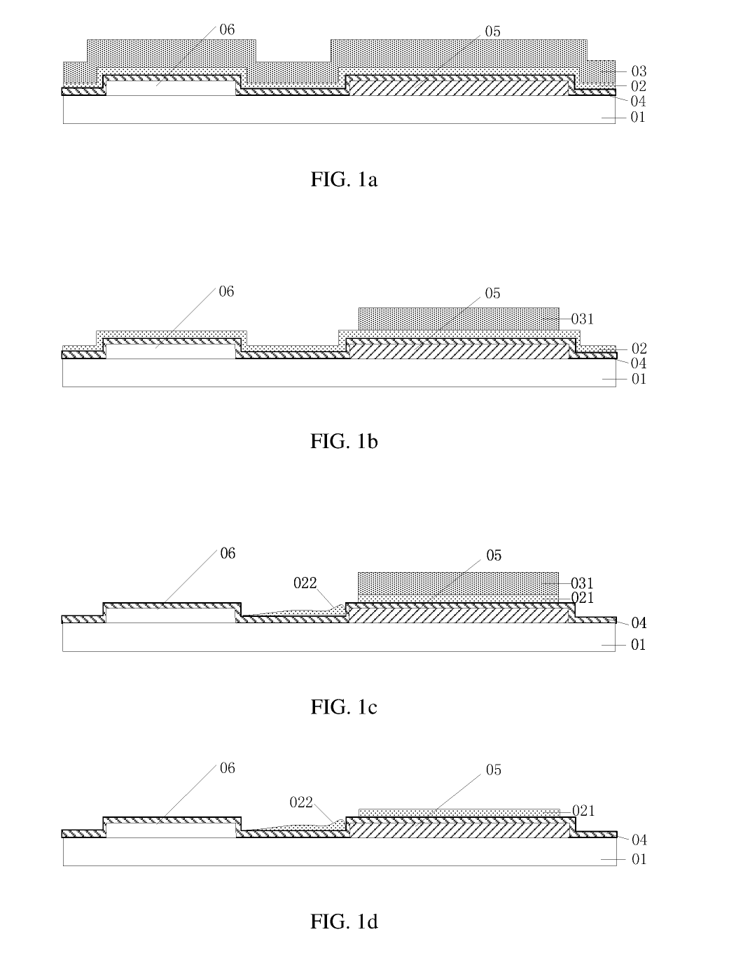

By taking an active layer for example, an active layer patterning method includes: as illustrated in FIG. 1a, sequentially forming a gate electrode pattern, an active layer thin film 02 and a photoresist layer thin film 03 on a base substrate 01; as illustrated in FIG. 1b, carrying out exposure and development on the photoresist layer thin film 03, and retaining photoresist 031 in a region corresponding to a to-be-formed active layer 021; as illustrated in FIG. 1c, etching the active layer thin film 02 to form a pattern of the active layer 021; and as illustrated in FIG. 1d, removing the photoresist 031 on the pattern of the active layer 021. FIG. 1c and FIG. 1d illustrate that after the active layer thin film 02 is etched, active layer residues 022 are left, and a main reason of generating the active layer residues is that foreign materials fall on the active layer thin film before the pattern of the active layer is formed by etching, so that a pattern region which should be etched off cannot be completely etched, thereby commonly forming defects of bright spots or mura and the like of a display image. For example, the above method may further include a common electrode 06 and forming a gate insulating layer 04 covering the common electrode 06 and the gate electrode 05 before forming the active layer 02. Viewed from analysis on actual survey data, by taking the active layer for example, about 90% of the active layer residues are from the foreign materials before dry etching, and thus, it is very important to protect the film from being damaged by the foreign materials before an etching process.

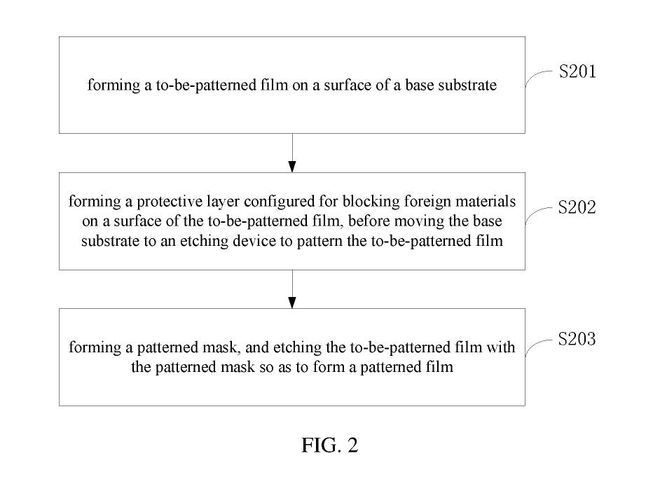

The present disclosure provides a film patterning method, as illustrated in FIG. 2, includes:
S201: forming a to-be-patterned film on a surface of the base substrate;
S202: forming a protective layer for blocking the foreign materials on a surface of the to-be-patterned film, before moving the base substrate to an etching device to pattern the to-be-patterned film; and
S203: forming a patterned mask, and etching the to-be-patterned film with the patterned mask so as to form a patterned film.

For example, before the patterned mask is formed, the protective layer completely covers a to-be-removed region and a to-be-retained region of the to-be-patterned film.

For example, the patterned mask is obtained by patterning the protective layer.

According to the film patterning method provided by the embodiment of the present disclosure, firstly, the to-be-patterned film is formed on the surface of the base substrate; then the protective layer for blocking the foreign materials is formed on the surface of the to-be-patterned film before the base substrate is moved to the etching device to carry out patterning on the to-be-patterned film; and finally, the protective layer is removed, the patterned mask is formed, and etching is carried out on the to-be-patterned film by the patterned mask so as to form the patterned film. The protective layer for blocking the foreign materials is formed on the surface of the to-be-patterned film, and thus, in the process of moving the to-be-patterned film with the protective layer to the etching device and until an etching process is carried out, adhesion between the foreign materials and the to-be-patterned film can be resisted, and influence of the foreign materials on the to-be-formed patterned film in the etching process can be effectively blocked, thereby fulfilling the aim of improving product yield.

In some examples, according to the film patterning method provided by the present disclosure, the to-be-patterned film includes the to-be-removed region and the to-be-retained region.

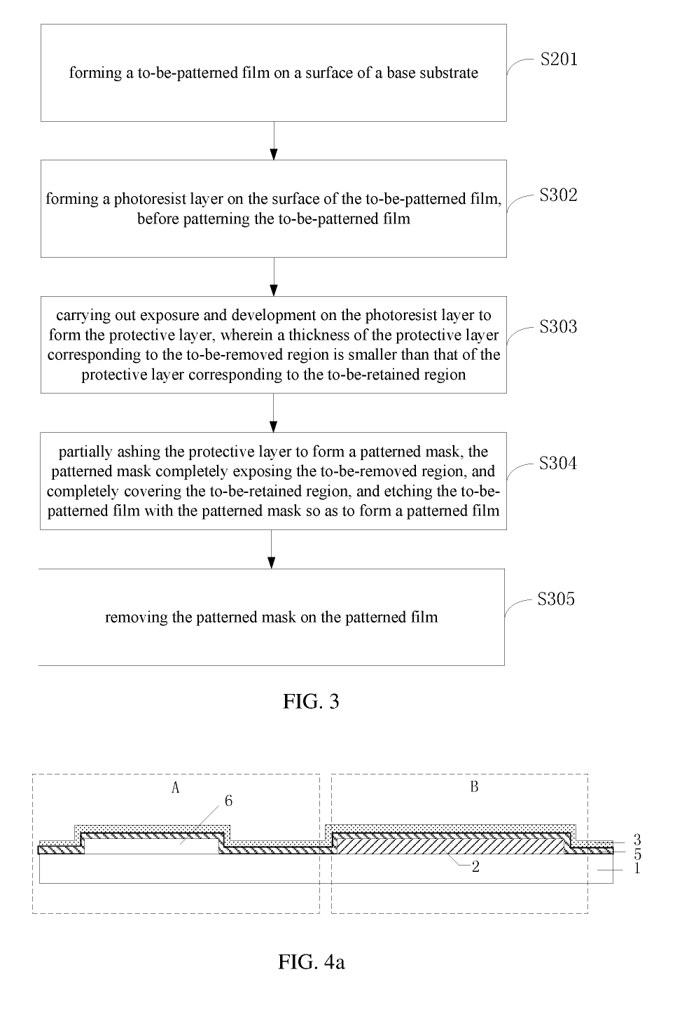

In some examples, according to the film patterning method provided by the present disclosure, in order to enable parts of a pattern of the protective layer, which correspond to the to-be-removed region and the to-be-retained region of the to-be-patterned film, to have different thicknesses so as to form the patterned mask in the process of removing the protective layer in a next step, and enable the protective layer to take an effect of protecting the to-be-patterned film from being damaged by the foreign materials, the protective layer for blocking the foreign materials is formed on the surface of the to-be-patterned film before the to-be-patterned film is patterned, as illustrated in FIG. 3, for example, which can be achieved as follows:
S301: forming a photoresist layer on the surface of the to-be-patterned film, before patterning the to-be-patterned film; and
S302: carrying out exposure and development on the photoresist layer to form the protective layer, wherein a thickness of the protective layer correspondingly covering the to-be-removed region is smaller than that of the protective layer correspondingly covering the to-be-retained region.

For example, in the film patterning method provided by the present disclosure, the step S302 of carrying out exposure and development on the photoresist layer to form the protective layer can be achieved as follows:

carrying out exposure and development on the photoresist layer with a mask plate so as to form the protective layer.

It should be illustrated that the photoresist layer is exposed and developed by changing a transmittance of a pattern of the mask plate so as to form the protective layer, and generally, 50% to 80% of transmittance is adopted, which can ensure that a photoresist partially-retained region (i.e., the photoresist in the region is incompletely exposed, and a certain thickness of photoresist is retained) is formed in a region corresponding to the to-be-removed region of the to-be-patterned film, and a photoresist completely-retained region (i.e., the photoresist in the region is not exposed) is formed in a region corresponding to the to-be-retained region of the to-be-patterned film, and thus, the thickness of the protective layer correspondingly covering the to-be-removed region can be smaller than that of the protective layer correspondingly covering the to-be-retained region. The photoresist layer also can be exposed and developed in modes of regulating illumination intensity and the like as long as the photoresist layer is enabled to obtain the photoresist completely-retained region and the photoresist partially-retained region, which is not limited to the mode of adopting the pattern of the mask plate and is not defined herein.

For example, in the film patterning method provided by the present disclosure, when the mask plate is adopted to carry out exposure and development on the photoresist layer, in order to reach a predetermined transmittance, the mask plate can be selected to be a halftone mask plate, a graytone mask plate or a mask plate with a slit. For example, the mask plate provided by the present disclosure can be of a random structure suitable for changing the transmittance, but not limited to the mask plate structure provided by the present disclosure.

In some examples, according to the film patterning method provided by the present disclosure, in order to facilitate carrying out the next step of etching process so as to form the patterned film, the step S203 of removing the protective layer and forming the patterned mask, as illustrated in FIG. 3, for example, can be carried out as follows:
S303: partially ashing the protective layer, to remove a part of the protective layer, which correspondingly covers the to-be-removed region, and thin a part of the protective layer, which correspondingly covers the to-be-retained region, so as to form the patterned mask, wherein the patterned mask completely exposes the to-be-removed region, and completely covers the to-be-retained region.

It should be illustrated that in the process of treating the protective layer in the etching device by an ashing process, the thickness of the protective layer correspondingly covering the to-be-removed region is smaller than that of the protective layer correspondingly covering the to-be-retained region, and thus, when the protective layer correspondingly covering the film in the to-be-removed region is completely removed, the ashing process is stopped, and at the moment, only a top half part of the protective layer correspondingly covering the film in the to-be-retained region is removed and the rest part of the protective layer can be used as the patterned mask so as to facilitate carrying out the next step of etching process. For example, the protective layer treated by the ashing process is used as the patterned mask for carrying out etching on the to-be-patterned film without adding a new mask, which can simplify a process and save cost.

In some examples, after the step S203 of forming the patterned film is executed, the film patterning method provided by the present disclosure, as illustrated in FIG. 3, can further include:
S304: removing the patterned mask on the patterned film. After the patterned mask is removed, the completed pattern of the patterned film without residues can be obtained.

For example, in the film patterning method provided by the present disclosure, the patterned film can be an active layer, an ohmic contact layer, a source/drain electrode, a pixel electrode layer or a touch control electrode layer, i.e., the film can be arranged on a display substrate, or can be arranged on a touch control substrate. It should be illustrated that as long as a film has a pattern, the film can adopt the fabrication method provided by the present disclosure, which is not defined herein.

By one specific embodiment, the active layer patterning method provided by the present disclosure will be illustrated in detail, and a process of producing a pattern of an active layer includes steps as follows.

Step 1: sequentially forming a pattern of a gate electrode and an active layer thin film on a surface of a base substrate.

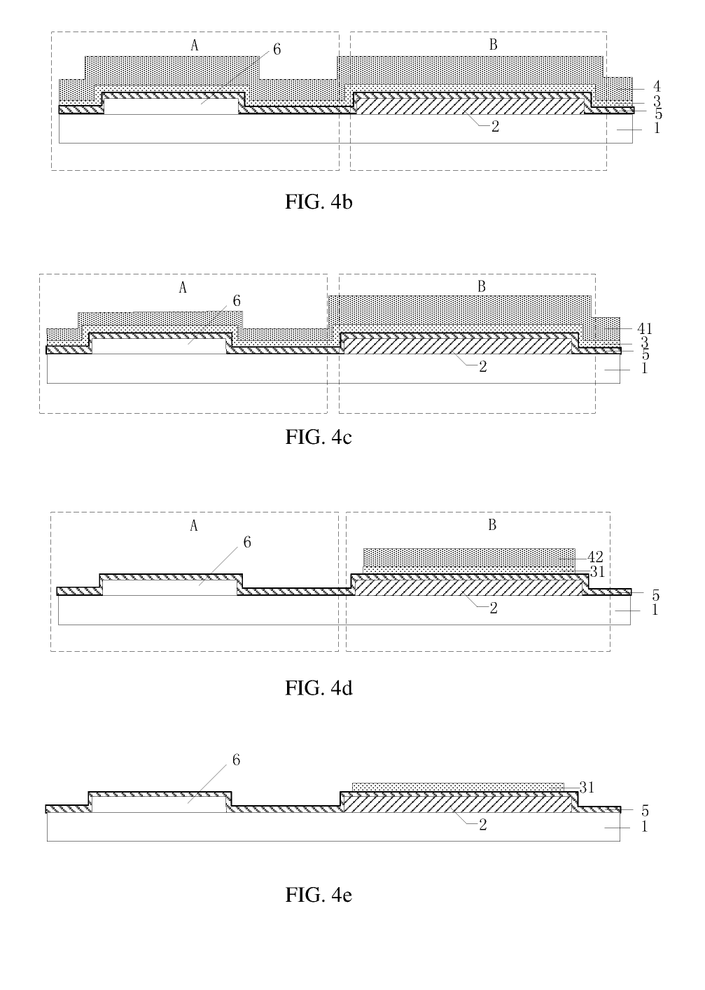

For example, as illustrated in FIG. 4a, firstly, a pattern of a gate electrode 2 is formed on the base substrate 1; then the active layer thin film 3 is formed on the base substrate on which the pattern of the gate electrode 2 is formed; and at the moment, the active layer thin film 3 is an to-be-patterned film, and the active layer thin film 3 includes a to-be-removed region A and a to-be-retained region B.

In some example, a common electrode 6 can also be formed in this step. In some examples, a gate insulating film 5 covering the common electrode 6 and the gate electrode 2 can be formed before forming the active layer thin film 3.

Step 2: forming a photoresist layer on a surface of the active layer thin film before patterning the active layer thin film.

For example, as illustrated in FIG. 4b, before the active layer thin film 3 is patterned, the photoresist layer 4 is formed on the surface of the active layer thin film 3.

Step 3: carrying out exposure and development on the photoresist layer to form a protective layer, wherein the thickness of the protective layer correspondingly covering the to-be-removed region is smaller than that of the protective layer correspondingly covering the to-be-retained region.

For example, as illustrated in FIG. 4c, the photoresist layer 4 is exposed and developed to form the protective layer 41; particularly, a halftone mask plate, a graytone mask plate or a mask plate with a slit can be adopted to carry out exposure and development on the photoresist layer 4 so as to form the protective layer 41, and at the moment, the thickness of the protective layer 41 in the to-be-removed region A is smaller than that of the protective layer 41 in the to-be-retained region B.

Step 4: partially ashing the protective layer to form a patterned mask, enabling the patterned mask to completely expose the to-be-removed region and completely cover the to-be-retained region, and etching the active layer thin film by the patterned mask so as to form the active layer.

For example, as illustrated in FIG. 4d, after the development process in Step 3 is completed, the active layer thin film 3 with the protective layer 41 is moved into an etching device, and in the etching device, in order to facilitate carrying out the next step of etching process, the protective layer 41 after exposure and development is treated by an ashing process, and the protective layer 41 is partially removed by a thickness corresponding to that covering the to-be-removed region so as to form the patterned mask 42; the patterned mask 42 completely exposes the to-be-removed region A, and completely covers the to-be-retained region B; and then, the active layer thin film 3 is etched with the patterned mask 42 to form the pattern of the active layer 41.

Step 5: removing (e.g., stripping) the patterned mask on the pattern of the active layer.

For example, as illustrated in FIG. 4e, after a dry etching process in Step 4 is completed, the patterned mask 42 on the pattern of the active layer 31 is stripped off, so that the complete pattern of the active layer 31 without residues is obtained.

For example, forming the patterned mask is carried out in the etching device.

For example, partially ashing the protective layer is carried out in the etching device.

So far, the film provided by the embodiments of the present disclosure is produced through Steps 1 to 5 provided by the specific embodiment.

The present disclosure provides a film patterning method. The method comprises: firstly, forming the to-be-patterned film on the surface of the base substrate; then, before moving the base substrate to the etching device to pattern the to-be-patterned film, forming the protective layer for blocking the foreign materials on the surface of the to-be-patterned film; and finally, removing the protective layer, forming the patterned mask, and etching the to-be-patterned film by the patterned mask so as to form the patterned film. Therefore, in the process of moving the to-be-patterned film with the protective layer to the etching device and until the etching process is carried out, adhesion between the foreign materials and the to-be-patterned film can be avoided, and influence of the foreign materials on the to-be-formed patterned film in the etching process can be effectively blocked, thereby fulfilling the aim of improving product yield.

The embodiments above are described by taking the patterned active layer thin film for example; however, the embodiments according to the present disclosure are not limited thereto.

The foregoing embodiments merely are exemplary embodiments of the disclosure, and not intended to define the scope of the disclosure, and the scope of the disclosure is determined by the appended claims.

The application claims priority of Chinese Patent Application No. 201510614255.1 filed on Sep. 23, 2015, the disclosure of which is incorporated herein by reference in its entirety as part of the present application.

1. A film patterning method,
comprising:
forming a to-be-patterned film on a surface of a base substrate, the to-be-patterned film includes a to-be-removed region and a to-be-retained region;
forming a protective layer configured for blocking foreign materials on a surface of the to-be-patterned film, before moving the base substrate to an etching device to pattern the to-be-patterned film, by carrying out exposure and development on a photoresist layer formed on the surface of the to-be-patterned film, wherein the protective layer completely covers the to-be-removed region and the to-be-retained region of the to-be-patterned film;
forming a patterned mask by partially asking the protective layer, wherein the patterned mask completely exposes the to-be-removed region, and completely covers the to-be-retained region; and
etching the to-be-patterned film with the patterned mask so as to form a patterned film.

2-4. (canceled)

5. The method according to claim 1, wherein forming the protective layer configured for blocking foreign materials on the surface of the to-be-patterned film before patterning the to-be-patterned film includes:
a thickness of the protective layer correspondingly covering the to-be-removed region is smaller than that of the protective layer correspondingly covering the to-be-retained region.

6. The method according to claim 5, wherein carrying out exposure and development on the photoresist layer to form the protective layer includes:
carrying out exposure and development on the photoresist layer with a mask plate so as to form the protective layer.

7. The method according to claim 6, wherein the mask plate is a halftone mask plate, a graytone mask plate or a mask plate with a slit.

8. The method according to claim 5,
wherein forming the patterned mask includes:
partially asking the protective layer, to remove a part of the protective layer correspondingly covering the to-be-removed region, and thin a part of the protective layer correspondingly covering the to-be-retained region, so as to form the patterned mask.

9. The method according to claim 8, after forming the patterned film, further comprising:
removing the patterned mask on the patterned film.

10. The method according to claim 1, wherein the patterned film is at least one selected from the group consisted of an active layer, an ohmic contact layer, a source/drain electrode, a pixel electrode layer and a touch control electrode layer.

11. The method according to claim 1, wherein forming the patterned mask is carried out in the etching device.

12. The method according to claim 8, wherein partially asking the protective layer is carried out in the etching device.

13. The method according to claim 1, wherein the protective layer is made of a photoresist material.
